(19) United States
(12) Patent Application Publication
(10) Pub. No.: US 2024/0328827 A1
(43) Pub. Date: Oct. 3, 2024

(54) INDUCTION DEVICE AND METHOD FOR SENSING EXTERNAL DEVICE BY INDUCTION DEVICE

(71) Applicant: Samsung Electronics Co., Ltd., Suwon-si (KR)

(72) Inventors: Kyungmin LEE, Suwon-si (KR); Jinsoo Choi, Suwon-si (KR); Sungbum Park, Suwon-si (KR); Sangwook Lee, Suwon-si (KR); Bohwan Choi, Suwon-si (KR)

(73) Assignee: Samsung Electronics Co., Ltd., Suwon-si (KR)

(21) Appl. No.: 18/744,014

(22) Filed: Jun. 14, 2024

Related U.S. Application Data
(63) Continuation of application No. PCT/KR2022/021434, filed on Dec. 27, 2022.

(30) Foreign Application Priority Data
Jan. 18, 2022 (KR) 10-2022-0007092

(51) Int. Cl. G01D 5/20; G01R 19/00; G01R 25/00; H05B 6/12

(52) U.S. Cl. CPC G01D 5/20; G01R 19/0092; G01R 25/00; H05B 6/1236

(57) ABSTRACT

An induction device includes: a wireless power transmission circuit; a current sensor; and at least one processor connected to the wireless power transmission circuit and the current sensor, wherein the at least one processor is configured to output first power for detecting of an external device through the wireless power transmission circuit, identify a first phase of a first current by measuring the first current flowing through a transmission coil of the wireless power transmission circuit using the current sensor while outputting the first power, in a first state where the external device is not in proximity, identify a phase delay value between the first phase of the first current and a second phase of a second current, and identify a second state where the external device is in proximity when the identified phase delay value is equal to or greater than a designated threshold.

### CROSS-REFERENCE TO RELATED APPLICATIONS

This application is a by-pass continuation application of International Application No. PCT/KR2022/021434, filed on Dec. 27, 2022, which is based on and claims priority to Korean Patent Application No. 10-2022-0007092, filed on Jan. 18, 2022, in the Korean Intellectual Property Office, the disclosures of which are incorporated by reference herein their entireties.

### BACKGROUND

### 1. Field

The disclosure relates to an induction device.

### 2. Description of the Related Art

Recently, electronic devices have developed into various forms for user convenience, and home appliances used at home are also developing into safe and convenient forms.

As a home appliance, an induction device (hereinafter also referred to as an “electronic device” or “electronic induction device”) is capable of induction heating as heating cooking equipment. The induction device may operate in electromagnetic induction in which a magnetic field is generated in a coil by applying high-frequency alternating current to the coil to heat a magnetic object placed on an induction coil. Since the induction device generates heat in a magnetic object inside an external device with high thermal efficiency, thereby shortening cooking time, and is better than gas ranges or electric ranges in safety, thermal efficiency, heating speed, and the like, it is widely used nowadays.

It may be convenient if the induction device is capable of transmitting wireless power using electromagnetic induction as well as induction heating. For example, the induction device may be convenient if it includes a wireless power transmission device such that a part (an induction heating device (or induction heating unit, an induction heater, or an induction heating part)) of the induction device heats the vessel and another part (a wireless power transmission device (or wireless power transmission circuit or wireless power transmission module)) of the induction device wirelessly transmits power to an external wireless power reception device.

There may be a variety of external devices capable of receiving wireless power through the wireless power transmission device included in the induction device. For example, external devices capable of receiving wireless power through the wireless power transmission device of the induction device may include various small home appliances such as toasters, blenders, and/or kettles. The external devices may require different wireless reception powers from each other.

The induction device may need to identify the wireless reception power required by each external device and transmit wireless power suitable for each external device.

### SUMMARY

According to an aspect of the disclosure, an induction device includes: wireless power transmission circuitry; a current sensor; and at least one processor connected to the wireless power transmission circuitry and the current sensor, wherein the at least one processor is configured to: output first power for detecting an external device through the wireless power transmission circuitry, identify a first phase of a first current by measuring the first current flowing through a transmission coil of the wireless power transmission circuitry using the current sensor while outputting the first power, in a first state where the external device is not in proximity, identify a phase delay value between the first phase of the first current and a second phase of a second current, and identify a second state where the external device is in proximity when the identified phase delay value is equal to or greater than a designated threshold, wherein the first state where the external device is in not proximity corresponds to a state where the external device is not on, not vertically above, or not near the induction device, and wherein the second state where the external device is in proximity corresponds to a state where the external device is on vertically above, or near the induction device.

According to an aspect of the disclosure, a method of detecting an external device in an induction device, includes: outputting first power for detecting the external device through wireless power transmission circuitry; measuring a first current flowing through a transmission coil of the wireless power transmission circuitry by using a current sensor while outputting the first power; identifying a first phase of the measured first current; in a first state where the external device is not in proximity, identifying a phase delay value between the first phase of the first current and a second phase of a second current; and when the identified phase delay value is equal to or greater than a designated threshold, identifying a second state where the external device is in proximity, wherein the first state where the external device is in not proximity corresponds to a state where the external device is not on, not vertically above, or not near the induction device, and wherein the second state where the external device is in proximity corresponds to a state where the external device is on vertically above, or near the induction device.

According to an aspect of the disclosure, a non-transitory storage medium storing instructions configured to cause, when executed by at least one processor, the at least one processor to perform at least one or more operations, wherein the at least one or more operations include: outputting first power for detecting an external device through wireless power transmission circuitry; measuring a first current flowing through a transmission coil of the wireless power transmission circuitry by using a current sensor while outputting the first power; identifying a first phase of the measured first current; in a first state where the external device is not in proximity, identifying a phase delay value between the first phase of the first current and a second phase of a second current; and identifying a second state where the external device is in proximity when the identified phase delay value is equal to or greater than a designated threshold.

According to one or more embodiments, it may be possible to more easily identify the type of external device using a phase difference of current flowing through the transmission coil in the induction device and transmit wireless power in an operation mode corresponding to the identified external device.

According to one or more embodiments, it may be possible to identify the type of external device from among a plurality of types depending on the difference between the phase of current flowing through the transmission coil when the external device is not present in the induction device and the phase of current flowing through the transmission coil when the external device is present, and transmit wireless power in a wireless power transmission method and wireless power transmission magnitude corresponding to the identified type of external device.

Advantageous effects obtainable from the disclosure may not be limited to the above mentioned effects, and other effects which are not mentioned may be clearly understood, through the following descriptions, by those skilled in the art to which the disclosure pertains.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram illustrating an induction device and external devices according to an embodiment;

FIG. 2 is a diagram illustrating the case in which an external device is not in proximity to an induction device and the case in which an external device is in proximity to an induction device according to an embodiment;

FIG. 3 is a graph illustrating current flowing through a transmission coil when an external device is not in proximity and when an external device is in proximity, respectively, while outputting ping power through the transmission coil in the induction device according to an embodiment;

FIG. 4 is a diagram illustrating the configuration of an induction device and an external device according to an embodiment;

FIG. 5 is a diagram illustrating an example of a phase delay corresponding to each of a plurality of external devices according to an embodiment;

FIG. 6 is a flowchart illustrating an operation of sensing an external device in an induction device according to an embodiment;

FIG. 7 is a diagram illustrating the waveform of current measured when an external device is not in proximity and the waveform of current measured when an external device is in proximity in the case where the resonance frequency of a transmission coil is 45 kHz according to an embodiment;

FIG. 8 is a configuration diagram of a hybrid induction device according to an embodiment;

FIG. 9A is a diagram illustrating an example of a hybrid induction device according to an embodiment;

FIG. 9B is a diagram illustrating an example in which an external device is placed on the exposed surface of a hybrid induction device according to an embodiment; and

FIG. 9C is a diagram illustrating an example in which cooking equipment is placed on the exposed surface of a hybrid induction device according to an embodiment.

### DETAILED DESCRIPTION

Hereinafter, an electronic device according to one or more embodiments will be discussed with reference to the accompanying drawings. As used in one or more embodiments, the term “user” may refer to a person who uses an electronic device or a device (e.g., artificial intelligence electronic device) which uses an electronic device.

The terms used in the disclosure are only used to describe specific embodiments, and may not be intended to limit the scope of other embodiments. A singular expression may include a plural expression unless they are definitely different in a context. Unless defined otherwise, all terms used herein, including technical and scientific terms, have the same meaning as those commonly understood by a person skilled in the art to which the disclosure pertains. Such terms as those defined in a generally used dictionary may be interpreted to have the meanings equal to the contextual meanings in the relevant field of art, and are not to be interpreted to have ideal or excessively formal meanings unless clearly defined in the disclosure. In some cases, even the term defined in the disclosure should not be interpreted to exclude embodiments of the disclosure.

Before undertaking the detailed description below, it may be advantageous to set forth definitions of certain words and phrases used throughout the disclosure. The term “couple” and the derivatives thereof refer to any direct or indirect communication between two or more elements, whether or not those elements are in physical contact with each other. The terms “transmit”, “receive”, and “communicate” as well as the derivatives thereof encompass both direct and indirect communication. The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” refers to any device, system, or part thereof that controls at least one operation. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. As an additional example, the expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

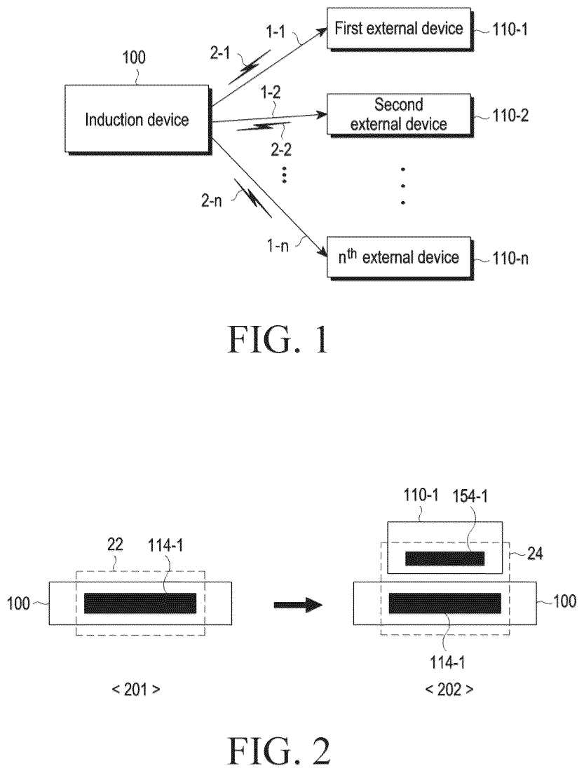

FIG. 1 is a diagram illustrating an induction device and external devices according to an embodiment.

Referring to FIG. 1, an induction device (or electronic induction device, electronic device, or wireless power transmission device) 100 according to an embodiment may wirelessly provide power 1-1, 1-2, and 1-n to at least one of external devices (or wireless power reception devices) 110-1 to 110-n, respectively. For example, the induction device 100 may wirelessly provide power to an authenticated external device that has performed a designated authentication procedure for wireless power transmission and reception.

The induction device 100 according to an embodiment may communicate with each of the external devices 110-1 to 110-n. For example, the induction device 100 and the respective external devices 110-1 to 110-n may process or transmit and receive packets 2-1 to 2-n configured as designated frames. For example, the induction device 100 may include a device capable of transmitting wireless power (wireless power transmission device), and the external devices 110-1 to 110-n may include an external wireless power reception device capable of receiving wireless power through the wireless power transmission device included in the induction device. For example, the external devices 110-1 to 110-n may include a first external device (e.g., a blender), a second external device (e.g., a kettle), a third external device (e.g., a toaster), and/or various other small home appliances.

The induction device 100 according to an embodiment may wirelessly transmit power to at least one of the external devices 110-1 to 110-n in a resonance manner. Each of the external devices 110-1 to 110-n according to an embodiment may perform a designated operation (or function) (e.g., a toaster function, a blender function, or a kettle function) using power transmitted from the induction device 100. For example, each of the induction devices 110-1 to 110-n may have a storage battery (or battery) capable of storing power transmitted from the external device 100 and perform a designated operation (or function) using the stored power.

The induction device 100 according to an embodiment may output the first power (e.g., ping power) for sensing (in other words, for detecting) an external device. The induction device 100 according to an embodiment may measure the current (e.g., a first current) of the transmission coil while outputting the first power. The induction device 100 according to an embodiment may identify a phase delay between a first phase of the measured first current and a second phase of a second current in the state where an external device is not in proximity while outputting the first power. If a phase delay value between the first phase of the measured first current and the second phase of the second current in the state where an external device is not in proximity is equal to or greater than (or exceeds) a designated threshold, the induction device 100 according to an embodiment may identify the state where the external device is in proximity. In the state where a phase delay value between the first phase of the measured first current and the second phase of the second current in the state where an external device is not in proximity is equal to or greater than a designated threshold, the induction device 100 according to an embodiment may identify the type of external device, based on the phase delay value between the first phase and the second phase. The induction device 100 according to an embodiment may store phase delay values corresponding to the respective external devices 110-1 to 110-n and identify (confirm or determine) a phase delay value corresponding to the delay value between the first phase and the second phase, from among the phase delay values of the external devices 110-1 to 110-n. For example, if the delay value between the first phase and the second phase is equal to a first phase delay value among the phase delay values of the external devices 110-1 to 110-n or similar thereto within a designated range, the induction device 100 may identify a first external device or a first type of external device corresponding to the first phase delay value. For example, if the delay value between the first phase and the second phase is equal to a second phase delay value among the phase delay values of the external devices 110-1 to 110-n or similar thereto within a designated range, the induction device 100 may identify a second external device or a second type of external device corresponding to the second phase delay value. The induction device 100 according to an embodiment may transmit wireless power, based on the identified external device or type of external device.

The external devices 110-1 to 110-n according to an embodiment may include different inductors (e.g., coils or reception coils) from each other, which induce different inductances with respect to the induction device 100. For example, the reception coil may include a magnetic material (e.g., ferrite) and a wire. For example, the first external device 110-1 may include a first ferrite, and the second external device 110-2 may include a second ferrite. The first inductance induced by the first power provided from the induction device 100 in the first reception coil of the first external device 110-1 may be different from the second inductance induced by the same in the second reception coil of the second external device 110-2 according to the difference between the first cross-section of the first ferrite and the second cross-section of the second ferrite (or difference in radius therebetween). For example, the external devices 110-1 to 110-n may have different induced values (e.g., inductances) from each other or between types thereof depending on the radius of the cross-section of the ferrite when exposed to a magnetic field. In other words, the external devices 110-1 to 110-n may have different radii of cross-section of ferrite from each other or between types thereof, and the inductance values induced by the first power (e.g., ping power) from the induction device 100 may be different from each other depending on the different radii of cross-section of ferrite. The resonance frequency may differ between the external devices 110-1 to 110-n because the inductance values induced by the first power (e.g., ping power) from the induction device 100 are different, so that the delay value of the phase of current flowing through the transmission coil of the induction device 100 may vary according thereto.

FIG. 2 is a diagram illustrating the case in which an external device is not in proximity to an induction device and the case in which an external device is in proximity to an induction device according to an embodiment.

Referring to FIG. 2, the induction device 100 according to an embodiment may output the first power (e.g., ping power) for sensing (for detecting) an external device through a transmission coil 114-1.

When the induction device 100 according to an embodiment outputs ping power through the transmission coil 114-1, the first inductance 22 may be induced according to the first cross-section of the ferrite included in the transmission coil 114-1 in state <201> in which an external device (e.g., the first external device 110-1) is not in proximity.

When the induction device 100 according to an embodiment outputs ping power through the transmission coil 114-1, the second inductance 24 corresponding to the first cross-section of the ferrite included in the transmission coil 114-1 and the second cross-section (corresponding to the increased cross-section) of the ferrite included in the reception coil 154-1 of the first external device 110-1 in state <202> in which an external device (e.g., the first external device 110-1) is in proximity.

Equation 1 below may be an equation for calculating the inductance of the coil.

$$L = \frac{{µ}_{0} {N}^{2} π {r}^{2}}{l} \qquad [ Equation 1 ]$$

In Equation 1 above, if N=nl,

$$L = \frac{{µ}_{0} {N}^{2} π {r}^{2}}{l} = {µ}_{0} {N}^{2} π {r}^{2} = {µ}_{0} {n}^{2} LA ,$$

L is the inductance of a cylindrical coil, μₒ is the permeability of free space, l is the length of the wire used in the coil, N is the number of turns of the coil, r is the radius of the coil cross-section, and A may represent the cross-sectional area of the coil.

Referring to Equation 1 above, the inductance may increase as the radius of the coil cross-section increases, and when ping power is output through the transmission coil (114-1), there may be the effect of substantially increasing the cross-section due to the additional reception coil 154-1 in addition to the transmission coil 114-1 in the state <202> where the external device (e.g., the first external device 110-1) is in proximity, compared to the state <201> where the external device is not in proximity, so that the inductance may increase as the cross-section increases, and the increased inductance may reduce the resonance frequency between the transmission coil 114-1 and the reception coil 154-1.

In other words, when the induction device 100 outputs ping power through the transmission coil 114-1, the inductance increases and the resonance frequency decreases in the state <202> where the external device (e.g., the first external device 110-1) is in proximity, so that the phase of current flowing through the transmission coil 114-1 of the induction device 100 may be delayed compared to the state <201> where the external device is not in proximity.

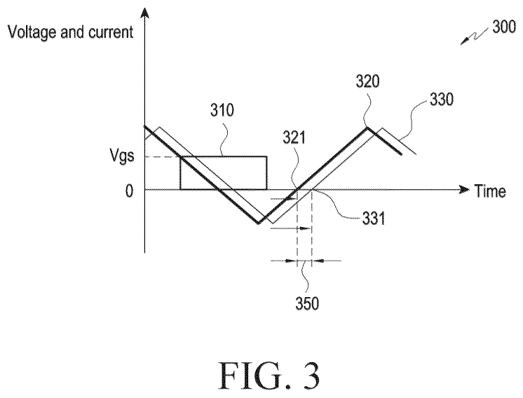

FIG. 3 is a graph illustrating current flowing through a transmission coil when an external device is not in proximity and when an external device is in proximity, respectively, while outputting ping power through the transmission coil in the induction device according to an embodiment.

Referring to FIG. 3, in the graph 300 according to an embodiment, the horizontal axis may represent time, and the vertical axis may represent voltage and current. According to an embodiment, the induction device 100 may output first power (e.g., ping power) of a first voltage (e.g., Vgs) as a first voltage waveform 310 to sense an external device. For example, the first voltage waveform 310 may be output periodically during a designated time.

The induction device 100 according to an embodiment may measure the current flowing through the transmission coil 114-1 while outputting the first power (e.g., ping power) of the first voltage (e.g., Vgs). For example, the induction device 100, when outputting the first power (e.g., ping power) of the first voltage (e.g., Vgs), may measure the current, as a first current waveform 320, flowing through the transmission coil 114-1 in the state where an external device is not in proximity. For example, the induction device 100, when outputting the first power (e.g., ping power) of the first voltage (e.g., Vgs), may measure the current, as a second current waveform 330, flowing through the transmission coil 114-1 in the state where an external device is in proximity. The induction device 100 according to an embodiment, after applying the ping power, may identify (or confirm or determine) a phase delay value 350, based on the time difference between a first zero-crossing point 321 of the first current waveform 320 and a second zero-crossing point 331 of the second current waveform 330. The induction device 100 according to an embodiment may store a plurality of phase delay values respectively corresponding to the external devices, which are pre-stored (or acquired or configured through experiment), and identify an external device corresponding to the identified phase delay value 350 using the plurality of phase delay values. For example, the induction device 100 may compare the identified phase delay value 350 with the plurality of phase delay values to identify an external device corresponding to a phase delay value that is the same as the identified phase delay value 350, among the plurality of phase delay values, or is similar thereto within a predetermined range. For example, the induction device 100, when a first phase delay value is identified, may identify a first external device corresponding to a phase delay value that is the same as the first phase delay value, among the plurality of phase delay values, or is similar thereto within a designated range, or when a second phase delay value is identified, may identify a second external device corresponding to a phase delay value that is the same as the second phase delay value, among the plurality of phase delay values, or is similar thereto within a designated range

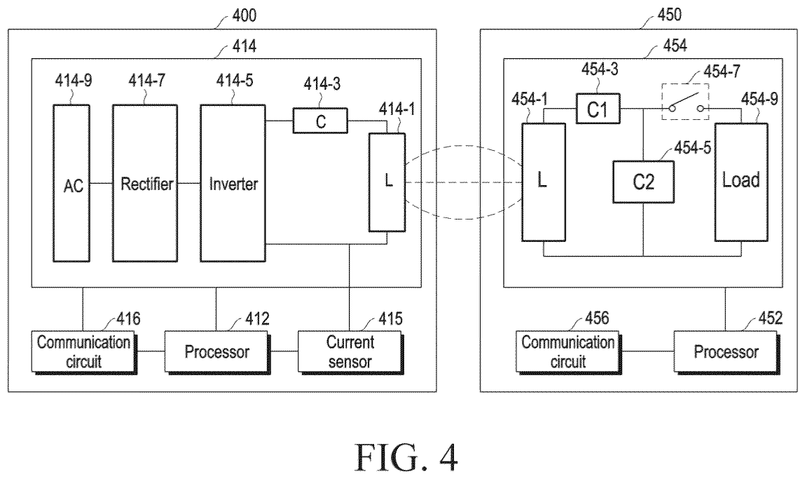

FIG. 4 is a diagram illustrating the configuration of an induction device and an external device according to an embodiment.

Referring to FIG. 4, an induction device 400 (e.g., the induction device 100 in FIG. 1) according to an embodiment may include a processor 412, power transmission circuitry (or a power transmission circuit) 414, a current sensor 415, and communication circuitry (or a communication circuit or a communication module) 416.

The processor 412 according to an embodiment may include at least one micro-processing unit (MCU). The processor 412 according to an embodiment may perform control such that the power transmission circuit 414 outputs first power (e.g., ping power) for sensing an external device 450 through a transmission coil 414-1 before transmitting wireless power. The processor 412 according to an embodiment may obtain a value of the current (e.g., a first current) flowing through the transmission coil 414-1, which is measured using the current sensor 415, while outputting the first power through the power transmission circuit 414. The processor 412 according to an embodiment may identify a first phase of the measured first current. The processor 412 according to an embodiment may compare a first phase of the measured first current with a second phase of a second current in the state where an external device is not in proximity while outputting the first power, thereby determining a phase delay between the first phase and the second phase. The processor 412 may correspond to at least one processor (one or more processors).

Table 1 below shows examples of the phase delay between the first phase of the first current measured in the state where an external device is not in proximity and the second phase of the second current in the state where an external device is not in proximity while outputting the first power.

TABLE 1

| | Phase delay | Phase delay | Phase delay |
|---|---|---|---|
| | @70 kHz (μs) | @50 kHz(μs) | @45 kHz(μs) |
| External device is in | 2.6 | 3.5 | 3.8 |
| proximity | | | |
| External device is not | 2.4 | 3.3 | 3.5 |
| in proximity | | | |

Referring to Table 1, in the case where the resonance frequency of the transmission coil 414-1 is about 70 kHz, if the first zero-crossing point value of the first current measured in the state where an external device is in proximity is about 2.6 μs and if the second zero-crossing point value of the second current measured in the state where an external device is not in proximity is about 2.4 μs, the processor 412 according to an embodiment may identify, as a phase delay value, the time difference (e.g., about 0.2 μs) between the first zero-crossing point value and the second zero-crossing point value, and identify an external device corresponding to the identified phase delay value. In the case where the resonance frequency of the transmission coil 414-1 is about 50 kHz, if the first zero-crossing point value of the first current measured in the state where an external device is in proximity is about 3.5 μs and if the second zero-crossing point value of the second current measured in the state where an external device is not in proximity is about 3.3 μs, the processor 412 according to an embodiment may identify, as a phase delay value, the time difference (e.g., about 0.2 μs) between the first zero-crossing point value and the second zero-crossing point value, and identify an external device corresponding to the identified phase delay value. In the case where the resonance frequency of the transmission coil 414-1 is about 45 kHz, if the first zero-crossing point value of the first current measured in the state where an external device is in proximity is about 3.8 μs and if the second zero-crossing point value of the second current measured in the state where an external device is not in proximity is about 3.5 μs, the processor 412 according to an embodiment may identify, as a phase delay value, the time difference (e.g., about 0.5 μs) between the first zero-crossing point value and the second zero-crossing point value, and identify an external device corresponding to the identified phase delay value. The processor 412 according to an embodiment, if the phase delay value between the first phase of the measured first current and the second phase of the second current in the state where the external device is not in proximity is greater than or equal to (or exceeds) a designated threshold, may identify the state where the external device is in proximity. In the state where the phase delay value between the first phase of the measured first current and the second phase of the second current in the state where the external device is not in proximity is greater than or equal to a designated threshold, the processor 412 according to an embodiment, based on the phase delay value between the first phase and the second phase, the type of external device. The processor 412 according to an embodiment may store phase delay values respectively corresponding to the external devices 110-1 to 110-n and identify (confirm or determine) a phase delay value corresponding to the delay value between the first phase and the second phase, from among the phase delay values of the external devices 110-1 to 110-n. For example, if the delay value between the first phase and the second phase is equal to a first phase delay value among the phase delay values of the external devices 110-1 to 110-n or similar thereto within a designated range, the processor 412 may identify a first external device or a first type of external device corresponding to the first phase delay value. For example, if the delay value between the first phase and the second phase is equal to a second phase delay value among the phase delay values of the external devices 110-1 to 110-n or similar thereto within a designated range, the processor 412 may identify a second external device or a second type of external device corresponding to the second phase delay value. The induction device 100 according to an embodiment may transmit wireless power, based on the identified external device or type of external device. The power transmission circuit 214 according to an embodiment may output first power (ping power) before transmitting wireless power under the control of the processor 212 and output second power when transmitting wireless power to the external device 450 sensed by the first power.

The power transmission circuit 414 according to an embodiment may include a transmission coil 414-1, a capacitor 414-3, an inverter 414-5, a rectifier 414-7, and an alternating-current power generator 414-9. The alternating-current power generator 414-9 according to an embodiment may generate alternating-current power. The rectifier 414-7 and the inverter 414-5 according to an embodiment may convert alternating-current power into direct-current power. The transmission coil 414-1 and the capacitor 414-3 according to an embodiment may output direct-current power in high frequency (RF).

The current sensor 415 according to an embodiment may measure (or sense) the current flowing through the transmission coil 414-1. For example, the current sensor 415 may sense the state of an output signal from the induction device 400, for example, the current level (or voltage level or power level), while outputting the first power. For example, the current sensor 415 may measure a signal in the power transmission circuit 414. For example, the current sensor may measure a signal in at least some areas of the transmission coil 414-1, capacitor 414-3, inverter 414-5, rectifier 414-7, and alternating-current power generator 414-9. For example, the current sensor 415 may include a circuit that measures a signal prior to the transmission coil 414-1. According to one or more embodiments, the induction device 400 may also sense the state of an output signal from the induction device 400, for example, the current level (or voltage level or power level), while outputting the first power using a voltage sensor or a power sensor, instead of the current sensor 415.

The communication circuit (or communication circuitry) 416 according to an embodiment may communicate with the external device 450. For example, the communication circuit 416 may communicate with a communication circuit 456 of the external device 450 using the same frequency as the frequency used by the transmission coil 414-1 to transmit power when transmitting wireless power (e.g., the in-band method). Alternatively, the communication circuit 416 may communicate with the communication circuit 456 of the external device 450 using a frequency different from the frequency used for power transmission in the transmission coil 414-1 (e.g., the out-band method). For example, when using the out-band method, the communication circuit 416 may obtain information (e.g., voltage information, current information, various packets, messages, or the like) related to the wireless power reception state of the external device 450 from the external device 450 using any one of various short-range communication methods such as Bluetooth, Bluetooth-low-energy (BLE), Wi-Fi, and near-field communication (NFC).

According to an embodiment, the external device 450 (e.g., one of the external devices 110-1 to 110-n in FIG. 1) may include a processor 452, power reception circuitry 454, and a communication circuit 456.

The processor 452 according to an embodiment may control the power reception circuitry 454 and the communication circuit 456. The processor 452 according to an embodiment may perform control such that a switch 454-7 of the power reception circuitry 454 is turned off before receiving wireless power and turned on when receiving wireless power (e.g., when wireless power begins to be received based on sensing ping power). For example, the processor 452 may perform control to turn on or off the switch 454-7, based on an power-on or -off input or an operation start or end input from the user, or perform control to turn on or off the switch 454-7, based on meeting a designated condition (e.g., the voltage or current measured due to resonance with the induction device 400 in the power-off state is equal to or greater than a designated voltage or current or less than that). The processor 452 according to an embodiment may control a designated operation (or function) (e.g., a blender function, a kettle function, or a toaster function) to be performed using the power received according to wireless power reception through the power reception circuitry 454 in the state where the switch 454-7 is turned on.

The power reception circuitry 454 according to an embodiment may include a reception coil 454-1, a first capacitor (C1) 454-3, a second capacitor (C2) 454-5, a switch 454-7, and a load 454-9. The power reception circuitry 454 according to an embodiment, based on the control of the processor 452, may turn off the switch 454-7 before the operation of receiving wireless power (or before receiving wireless power) such that the reception coil 454-1, the first capacitor (C1) 454-3, and the second capacitor (C2) 454-5 are disconnected from the load 454-9. Upon sensing ping power, the power reception circuitry 454 according to an embodiment may turn on the switch 454-7 when operating to receive wireless power (or when receiving wireless power) under the control of the processor 452 such that the reception coil 454-1, the first capacitor (C1) 454-3, and the second capacitor (C2) 454-5 are connected to the load 454-9. For example, the first capacitor (C1) 454-3, and the second capacitor (C2) 454-5 may participate in resonance with the induction device 400 in the state where the switch 454-7 is turned off, the reception coil 454-1, and the reception coil 454-1, the first capacitor (C1) 454-3, and the second capacitor (C2) 454-5, and the load 454-9 may participate in resonance with the induction device 400 in the state where the switch 454-7 is turned on.

The communication circuit 456 according to an embodiment may communicate with the communication circuit 416 of the induction device 400. For example, the communication circuit 456 may communicate with the communication circuit 416 of the induction device 400 using the same frequency as the frequency used by the transmission coil 414-1 to transmit power when transmitting wireless power (e.g., the in-band method). Alternatively, the communication circuit 456 may communicate with the communication circuit 416 of the induction device 400 using a frequency different from the frequency used for power transmission in the transmission coil 414-1 (e.g., the out-band method). For example, when using the out-band method, the communication circuit 456 may transmit, to the induction device 400, information (e.g., voltage information, current information, various packets, messages, or the like) related to the wireless power reception state using any one of various short-range communication methods such as Bluetooth, Bluetooth-low-energy (BLE), Wi-Fi, and near-field communication (NFC).

According to an embodiment, the induction device 400 may further include memory that may store programs (or instructions) and data for operation of the processor 412 and store phase delay values corresponding to the respective external devices 110-1 to 110-n.

According to one or more embodiments, an induction device (e.g., the wireless power transmission device 100 in FIG. 1 or the induction device 400 in FIG. 4) may include wireless power transmission circuit (e.g., the wireless power transmission circuit 414 in FIG. 4), a current sensor (e.g., the current sensor 415 in FIG. 4), and a processor (e.g., the processor 412 in FIG. 4) connected to the wireless power transmission circuit and the current sensor, wherein the processor may be configured to output first power for sensing an external device through the wireless power transmission circuit, identify a first phase of a first current by measuring the first current flowing through a transmission coil of the wireless power transmission circuit using the current sensor while outputting the first power, identify a phase delay value between the first phase of the first current and a second phase of a second current in the state where an external device is not in proximity, and identify the state where an external device is in proximity when the identified phase delay value is equal to or greater than a designated threshold.

According to one or more embodiments, the processor may be configured to identify a first external device corresponding to a first phase delay value when the identified phase delay value is the first phase delay value in the state where the identified phase delay value is equal to or greater than the designated threshold and identify a second external device corresponding to a second phase delay value when the identified phase delay value is the second phase delay value.

According to one or more embodiments, the induction device may further include memory configured to store a plurality of phase delay values respectively corresponding to a plurality of external devices.

According to one or more embodiments, the processor may be configured to identify an external device corresponding to the identified phase delay value from among the plurality of external devices by using the plurality of phase delay values respectively corresponding to the plurality of external devices.

According to one or more embodiments, the processor may be configured to identify the phase delay, based on a difference between a second crossing point value of the second current in the state where the external device is not in proximity and a first crossing point value of the measured first current.

According to one or more embodiments, the processor may be configured to output the first power for sensing an external device through the wireless power transmission circuit, based on a designated resonance frequency.

According to one or more embodiments, the induction device may further include a communication circuit,

According to one or more embodiments, the communication circuit may be configured to communicate with the external device by an in-band or out-band scheme.

According to one or more embodiments, the induction device may further include an induction heater, and the processor may be configured to control the induction heater and the wireless power transmission circuit, respectively.

According to one or more embodiments, the induction device may further include an input, and the processor may be configured to perform electromagnetic induction heating through the induction heater when an input for induction heating is received through the input.

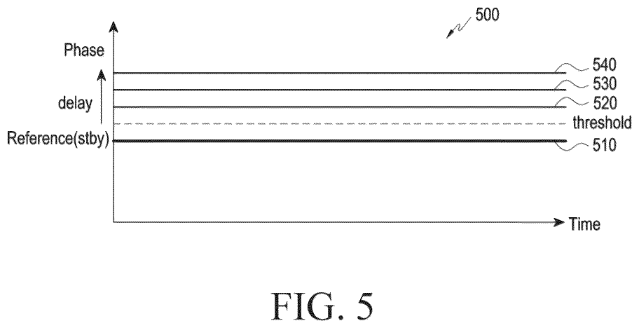

FIG. 5 is a diagram illustrating an example of a phase delay corresponding to each of a plurality of external devices according to an embodiment.

Referring to FIG. 5, in the phase graph 500 according to an embodiment, the horizontal axis may represent time, and the vertical axis may represent phase. According to an embodiment, in the case where the phase is a first phase value 510 in the state where an external device is not in proximity (reference standby (stby)) when the induction device 400 outputs the first power (e.g., ping power) before transmitting wireless power, different phase delays may occur depending on the type of external device when an external device approaches.

According to an embodiment, if the difference (phase delay) between the first phase of the first current measured in the transmission coil 214-1 by the power transmission circuit 414 while outputting the first power and the second phase of the second current has a first phase delay 520, which exceeds a threshold, the processor 412 may identify a first external device corresponding to the first phase delay value between the first phase value 510 (reference standby (stby)) and the first phase delay 520. According to an embodiment, if the difference (phase delay) between the first phase of the first current measured in the transmission coil 214-1 by the power transmission circuit 414 while outputting the first power and the second phase of the second current has a second phase delay 530, which exceeds a threshold, the processor 412 may identify a second external device corresponding to the second phase delay value. According to an embodiment, if the difference (phase delay) between the first phase of the first current measured in the transmission coil 214-1 while outputting the first power and the second phase of the second current has a third phase delay 540, which exceeds a threshold, the processor 412 may identify a third external device corresponding to the third phase delay value.

Although it has been described above that the first to third external devices are identified based on the first to third phase delay values, the processor 412 according to one or more embodiments may identify fewer different external devices, based on fewer different phase delay values, or identify more different external devices, based on more different phase delay values.

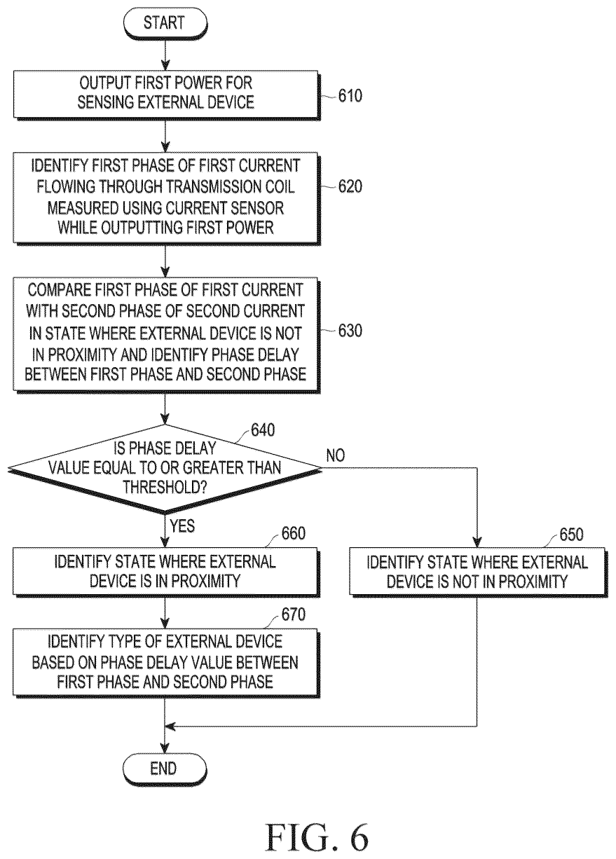

FIG. 6 is a flowchart illustrating an operation of sensing an external device in an induction device according to an embodiment.

Referring to FIG. 6, ae processor (e.g., the processor 412 in FIG. 4) of an induction device (e.g., the induction device 100 in FIG. 1 or the induction device 400 in FIG. 4) according to an embodiment may perform at least one of operations 610 to 670.

In operation 610, the processor 412 according to an embodiment may output first power (e.g., ping power) for sensing the external device 450 through the wireless power transmission circuit 414.

In operation 620, the processor 412 according to an embodiment may identify a first phase of current (e.g., a first current) flowing through the transmission coil 414-1 measured using the current sensor 415 while outputting the first power through the power transmission circuit 414.

In operation 630, the processor 412 according to an embodiment may compare the first phase of the measured first current with a second phase of a second current in the state where an external device is not in proximity while outputting the first power, and identify a phase delay between the first phase and the second phase.

In operation 640, the processor 412 according to an embodiment may identify whether a phase delay value between the first phase of the measured first current and the second phase of the second current in the state where an external device is not in proximity is equal to or greater than (or exceeds) a designated threshold.

In operation 650, the processor 412 according to an embodiment, based on the phase delay value between the first phase and the second phase being less than (or equal to or less than) the designated threshold, may identify the state where the external device is not in proximity and may end the sequence or return to operation 620.

In operation 660, the processor 412 according to an embodiment, based on the phase delay between the first phase and the second phase being greater than or equal to the threshold, may identify the state where the external device is in proximity. The state where the external device is in proximity may correspond to a state where the external device is on, vertically above, or near the induction device.

In operation 670, the processor 412 according to an embodiment may identify the type of external device, based on the phase delay value between the first phase and the second phase, in the state where the external device is in proximity. The processor 412 according to an embodiment, using a phase delay values respectively corresponding to the external devices 110-1 to 110-n stored in memory, may identify (confirm or determine) a phase delay value corresponding to the delay value between the first phase and the second phase, from among the phase delay values of the external devices 110-1 to 110-n. For example, if the delay value between the first phase and the second phase is equal to a first phase delay value among the phase delay values of the external devices 110-1 to 110-n or similar thereto within a designated range, the processor 412 may identify a first external device or a first type of external device corresponding to the first phase delay value. For example, if the delay value between the first phase and the second phase is equal to a second phase delay value among the phase delay values of the external devices 110-1 to 110-n or similar thereto within a designated range, the processor 412 may identify a second external device or a second type of external device corresponding to the second phase delay value. The processor 412 according to an embodiment may transmit wireless power to the external device, based on the identified external device or type of external device.

According to one or more embodiments, a method of sensing an external device in an induction device (e.g., the induction device 100 in FIG. 1 or the induction device 400 in FIG. 4) may include outputting first power for sensing an external device through wireless power transmission circuit, measuring a first current flowing through a transmission coil of the wireless power transmission circuit by using a current sensor while outputting the first power, identifying a first phase of the measured first current, identifying a phase delay value between the first phase of the first current and a second phase of a second current in the state where an external device is not in proximity, and identifying the state where an external device is in proximity when the identified phase delay value is equal to or greater than a designated threshold.

According to one or more embodiments, the method may further include identifying a first external device corresponding to a first phase delay value when the identified phase delay value is the first phase delay value in the state where the identified phase delay value is equal to or greater than the designated threshold, and identifying a second external device corresponding to a second phase delay value when the identified phase delay value is the second phase delay value.

According to one or more embodiments, the method may further include obtaining a plurality of phase delay values respectively corresponding to a plurality of external devices.

According to one or more embodiments, the method may further include identifying an external device corresponding to the identified phase delay value from among the plurality of external devices by using the plurality of phase delay values respectively corresponding to the plurality of external devices.

According to one or more embodiments, the method may further include identifying the phase delay, based on a difference between a second crossing point value of the second current in the state where the external device is not in proximity and a first crossing point value of the measured first current.

According to one or more embodiments, in the method, the first power for sensing an external device may be output through the wireless power transmission circuit, based on a designated resonance frequency.

According to one or more embodiments, the method may further include communicating with the external device in an in-band or out-band scheme.

According to one or more embodiments, the method may further include controlling the induction heater.

According to one or more embodiments, the method may further include performing electromagnetic induction heating through the induction heater when an input for induction heating is received through an input.

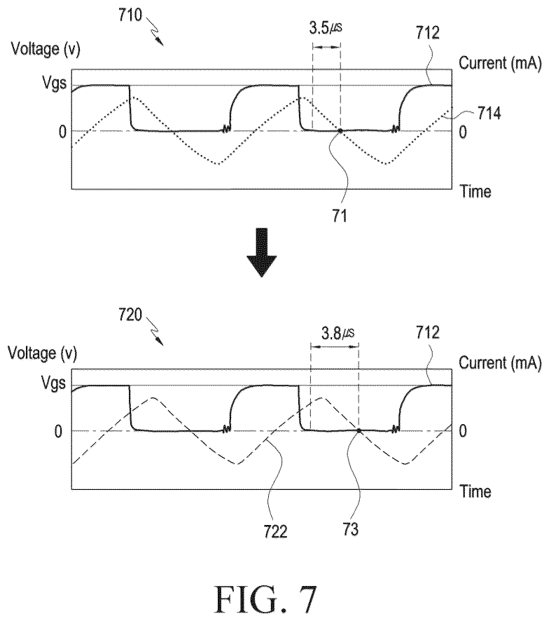

FIG. 7 is a diagram illustrating the waveform of current measured when an external device is not in proximity and the waveform of current measured when an external device is in proximity in the case where the resonance frequency of a transmission coil is 45 kHz according to an embodiment.

Referring to FIG. 7, a processor (e.g., the processor 412 in FIG. 4) of an induction device (e.g., the induction device 100 in FIG. 1 or the induction device 400 in FIG. 4) according to an embodiment may measure a second current flowing through a transmission coil (e.g., the transmission coil 414-1 in FIG. 4) in the state where the resonance frequency is 45 kHz and where an external device is not in proximity (710) while outputting first power (e.g., ping power) (712), thereby obtaining a second current waveform 714. According to the second current waveform 714 according to an embodiment, a value of the second zero-crossing point 71 of the second current measured in the state where the resonance frequency is 45 kHz and where an external device is not in proximity (710) while outputting the first power (e.g., ping power) (712) may be about 3.5 μs. The processor 412 according to an embodiment may measure first current flowing through the transmission coil (e.g., the transmission coil 414-1 in FIG. 4) in the state where the resonance frequency is 45 kHz and where an external device is in proximity (720) while outputting the first power (e.g., ping power) (712), thereby obtaining a first current waveform 722. According to the first current waveform 722 according to an embodiment, a value of the first zero-crossing point 73 of the first current measured in the state where the resonance frequency is 45 kHz and where an external device is in proximity (720) while outputting the first power (e.g., ping power) (712) may be about 3.8 μs. The processor 412 according to an embodiment may identify that the phase delay value between the second current flowing through the transmission coil (e.g., the transmission coil 414-1 in FIG. 4) in the state where an external device is not in proximity (710) and the first current flowing through the transmission coil (e.g., the transmission coil 414-1 in FIG. 4) in the state where an external device is in proximity (720) is 0.3 μs. The processor 412 according to an embodiment may identify an external device corresponding to the phase delay value. According to an embodiment, although it has been described by way of example in FIG. 7 based on the phase delay value between the second current flowing through the transmission coil 414-1 in the state where an external device is not in proximity (710) and the first current flowing through the transmission coil 414-1 in the state where an external device is in proximity (720) when the resonance frequency is 45 kHz, those skilled in the art will understand that the phase delay value is able to be identified in the same manner as in the case of 45 kHz even when using other resonant frequencies (e.g., 70 kHz, 50 kHz, or other resonant frequencies).

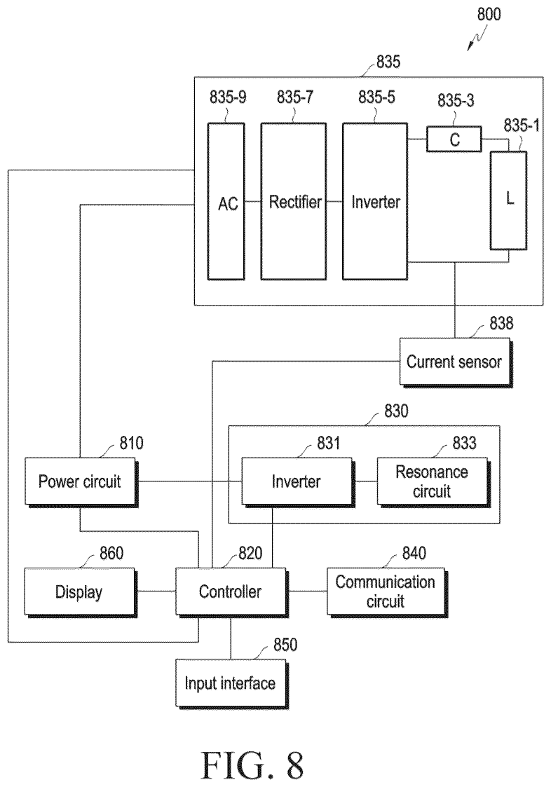

FIG. 8 is a configuration diagram of a hybrid induction device according to an embodiment.

Referring to FIG. 8, all of some of the configurations of an induction device (e.g., the induction device 100 in FIG. 1 or the induction device 400 in FIG. 4) according to an embodiment may be implemented to be included in a hybrid induction device 800. For example, the hybrid induction device 800 may be an induction device capable of inductively heating an external device and/or transmitting wireless power to an external device.

The hybrid induction device 800 according to an embodiment may be configured to include power circuitry 810, a controller (or control circuitry or a processor) 820, an induction heater (or induction heating unit) 830, a wireless power transmission circuit (or wireless power transmission circuitry or a wireless power transmission unit) 835, a communication circuit (or communication circuitry or a communication module) 840, an input interface (or input module) 850, and a display (or a display module) 860. Without being limited thereto, the hybrid electronic induction device 800 may be configured to further include a sound output circuit (or sound output circuitry or a sound output module), a sensor (or a sensor module), and/or memory.

According to an embodiment, the power circuitry 810 may be configured to receive power from an external power supply, convert the same to a voltage required for each element (e.g., the power circuitry 810, the controller 820, the induction heater 830, the wireless power transmission circuit 835, the communication circuit 840, the input interface 850, or the display 860 in FIG. 8, or other elements) and supply the converted required voltage to each element.

According to an embodiment, the controller 820 may include at least one processor (e.g., the processor 412 in FIG. 4). For example, the controller 820 may include a microcontroller unit (MCU) that is obtained by integrating a microprocessor and an input/output into one chip and is capable of various “control” or “computation tasks” through programming. The controller 820 may include a signal conversion circuitry connected to at least one processor.

According to an embodiment, the controller 820 of the hybrid induction device 800 may control the induction heater 830 and/or the wireless power transmission circuit 835, respectively. According to an embodiment, the controller 820 may perform control such that the induction heater 830 and the wireless power transmission circuit 835 operate simultaneously or such that one of the induction heater 830 and the wireless power transmission circuit 835 operates and the other does not operate.

According to an embodiment, if an input for induction-on (starting heating) (or induction heating operation) is received by a user input interface through the input interface 850, the controller 820 may supply power to the induction heater 830 to switch to an operation state, and perform electromagnetic induction heating through the induction heater 830. As a change in load is sensed, the controller 820 may identify that there is cooking equipment capable of induction heating in the partial area of the exposed surface.

According to an embodiment, if an input for transmitting wireless power is received by a user input interface through the input interface 850 or if an external device sensing event is received, the controller 820 may perform control such that the wireless power transmission circuit 835 outputs first power (e.g., ping power) for sensing an external device capable of receiving wireless power through the transmission coil 835-1 before transmitting wireless power. The controller 820 according to an embodiment may identify a first phase of current (e.g., a first current) flowing through the transmission coil 835-1, which is measured using the current sensor 836 while outputting the first power through the wireless power transmission circuit 835. The controller 820 according to an embodiment may compare the first phase of the measured first current with a second phase of a second current in the state where an external device is not in proximity while outputting the first power, thereby identifying a phase delay between the first phase and the second phase. The controller 820 according to an embodiment may identify whether a phase delay value between the first phase of the measured first current and the second phase of the second current in the state where an external device is not in proximity is equal to or greater than (or exceeds) a designated threshold. The controller 820 according to an embodiment, based on the phase delay value between the first phase and the second phase being less than (or equal to or less than) the designated threshold, may identify the state where the external device is not in proximity. The controller 820 according to an embodiment, based on the phase delay between the first phase and the second phase being equal to or greater than the threshold, may identify the state where the external device is in proximity. The controller 820 according to an embodiment may identify the type of external device, based on the phase delay value between the first phase in the state where an external device is in proximity and the second phase. The controller 820 according to an embodiment may store phase delay values corresponding to the respective external devices 110-1 to 110-n and identify (confirm or determine) a phase delay value corresponding to the delay value between the first phase and the second phase, from among the phase delay values of the external devices 110-1 to 110-n. For example, if the delay value between the first phase and the second phase is equal to a first phase delay value among the phase delay values of the external devices 110-1 to 110-n or similar thereto within a designated range, the controller 820 may identify a first external device or a first type of external device corresponding to the first phase delay value. For example, if the delay value between the first phase and the second phase is equal to a second phase delay value among the phase delay values of the external devices 110-1 to 110-n or similar thereto within a designated range, the controller 820 may identify a second external device or a second type of external device corresponding to the second phase delay value. The controller 820 according to an embodiment may transmit wireless power, based on the identified external device or type of external device.

The induction heater 830 according to an embodiment may include an inverter 831 and resonance circuitry 833 including a coil (e.g., an induction coil). The inverter 831 may be connected to signal conversion circuitry of the controller 820 and may convert direct-current voltage to alternating-current voltage. The inverter 831 may apply a high-frequency current corresponding to the frequency (f) configured or changed for output power control to the resonance circuitry 833 under the control of the controller 820. If a high-frequency current is applied to the coil of the resonance circuitry 833 and if cooking equipment capable of induction heating is present in a partial area of the exposed surface of the hybrid induction device 800, electromagnetic induction heating may be performed.

The wireless power transmission circuit 835 according to an embodiment may output first power (ping power) before transmitting wireless power under the control of the controller 820 and output second power to a wireless power reception device sensed by the first power when transmitting wireless power. The power transmission circuit 835 according to an embodiment may include a transmission coil 835-1, a capacitor 835-3, an inverter 835-5, a rectifier 835-7, and an alternating-current power generator 835-9. The alternating-current power generator 835-9 according to an embodiment may generate alternating-current power. The rectifier 835-7 and the inverter 835-5 according to an embodiment may convert alternating-current power into direct-current power. The transmission coil 835-1 and the capacitor 835-3 according to an embodiment may output direct-current power in high frequency (RF).

The current sensor 836 according to an embodiment may measure (or sense) the current flowing through the transmission coil 835-1. For example, the current sensor 836 may sense the state of an output signal from the hybrid induction device 800, for example, the current level (or voltage level or power level), while outputting the first power. For example, the current sensor 836 may measure a signal in the wireless power transmission circuit 835. For example, the current sensor 836 may measure a signal in at least some areas of the transmission coil 835-1, capacitor 835-3, inverter 835-5, rectifier 835-7, and alternating-current power generator 835-9. For example, the current sensor 836 may include a circuit that measures a signal prior to the transmission coil 835-1. According to one or more embodiments, the hybrid induction device 800 may also sense the state of an output signal from the hybrid induction device 800, for example, the current level (or voltage level or power level), while outputting the first power using a voltage sensor or a power sensor, instead of the current sensor 836.

The communication circuit 840 according to an embodiment may communicate with the external device. For example, the communication circuit 840 may communicate with a communication circuit of the wireless power reception device using the same frequency as the frequency used by the transmission coil 835-1 to transmit power when transmitting wireless power (e.g., the in-band method). Alternatively, the communication circuit 840 may communicate with the communication circuit of the wireless power reception device using a frequency different from the frequency used for transmitting power in the transmission coil 835-1 (e.g., the out-band method). For example, when using the out-band method, the communication circuit 840 may obtain information (e.g., voltage information, current information, various packets, messages, or the like) related to the wireless power reception state of the wireless power reception device from the wireless power reception device using any one of various short-range communication methods such as Bluetooth, Bluetooth-low-energy (BLE), Wi-Fi, and near-field communication (NFC).

According to an embodiment, the input interface (or user interface) 850 may receive an input related to operating functions of the hybrid induction device 800 and transmit the received user input to the controller 820. The input interface 850 may include menus (e.g., buttons or input interfaces) related to provided functions. Commands or data to be used in the elements (e.g., the controller 820) of the hybrid induction device 800 may be received from the outside (e.g., the user) of the hybrid induction device 800.

According to an embodiment, the display 860 may display objects representing menus (e.g., buttons or input interfaces) related to provided functions. The display 860 may be disposed in a partial area of the exposed surface of the hybrid induction device 800. Here, the partial area is different from the area where the resonance circuitry 833 is disposed. The display 860 may display notification information related to execution and/or interruption of the induction heating function and/or wireless power transmission function. The display 860 may display information according to the execution of functions provided by the hybrid induction device 800. The display 860 may visually provide information to the outside (e.g., the user) of the electronic induction device 800. The display 860 may include, for example, a display screen, a hologram device, or a projector, and a controller for controlling the device. According to an embodiment, the display 860 may include a touch sensor configured to sense a touch or a pressure sensor configured to measure the intensity of force generated by the touch.

According to an embodiment, a sound output circuit of the hybrid induction device 800 may output a sound signal to the outside of the electronic induction device 800. The sound output circuit may output notification information, as a sound signal, related to execution and/or interruption of the induction heating function and/or wireless power transmission function to the controller 820. The sound output circuit may output information, as a sound signal, according to the execution of the functions provided by the hybrid induction device 800. The sound output circuit may include, for example, a speaker or receiver. The speaker may be used for general purposes such as multimedia playback or recording playback. The receiver may be used to receive incoming calls. According to an embodiment, the receiver may be implemented separately from the speaker or as part of the same.

According to an embodiment, an audio circuit of the hybrid induction device 800 may convert sound into an electrical signal or, conversely, convert an electrical signal into sound. According to an embodiment, the audio circuit may obtain sound through the input interface 850 or output sound through the sound output circuit or an external electronic device (e.g., a speaker or a headphone) connected directly or wirelessly to the hybrid induction device 800.

According to an embodiment, a sensor of the hybrid induction device 800 may sense the operation state (e.g., power or temperature) of the hybrid induction device 800 or the external environmental state (e.g., a user state), and produce an electrical signal or data value corresponding to the sensed state. According to an embodiment, the sensor may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

According to an embodiment, a haptic circuit of the hybrid induction device 800 may convert an electrical signal into mechanical stimulation (e.g., vibration or movement) or electrical stimulation capable of being perceived by the user through tactile or kinesthetic senses. According to an embodiment, the haptic circuit may include, for example, a motor, a piezoelectric element, or an electrical stimulation device.

According to an embodiment, memory of the hybrid induction device 800 may store a variety of data used by at least one element (e.g., the processor or sensor) of the hybrid induction device 800. The data may include, for example, software (e.g., programs) and input data or output data for instructions associated therewith. The memory may include volatile memory or non-volatile memory. The programs may be stored, as software, in the memory and may include, for example, an operating system, middleware, or applications.

According to an embodiment, at least one processor included in the controller 820 may execute software (e.g., a program) to control at least one other element (e.g., hardware or software elements) of an electronic device connected to the processor and perform processing of a variety of data or calculations. According to an embodiment, as at least part of the data processing or calculations, the processor may store commands or data received from other elements (e.g., the sensor or the communication circuit 840) in volatile memory, process the commands or data stored in the volatile memory, and store the resulting data thereof in non-volatile memory. According to an embodiment, the processor may include a main processor (e.g., a central processing unit or an application processor) or an auxiliary processor (e.g., a graphics processing unit, a neural processing unit (NPU), an image signal processor, a sensor hub processor, or a communication processor) that is operable independently of the main processor or together therewith. For example, if the electronic induction device 600 includes a main processor and an auxiliary processor, the auxiliary processor may be configured to use lower power than the main processor or to be specialized for a designated function. The auxiliary processor may be implemented separately from the main processor or as part thereof.

As described above, the primary elements of the induction device have been described through the induction device 100 in FIG. 1, the induction device 400 in FIG. 4, and the hybrid induction device 800 in FIG. 8 in an embodiment. However, in one or more embodiments, not all of the elements shown in FIGS. 1, 4, and 8 are essential elements, and the induction device may be implemented to include more or fewer elements than the elements shown. In addition, the positions of the primary elements of the induction device described above with reference to FIGS. 1, 4, and 8 may vary depending on one or more embodiments.

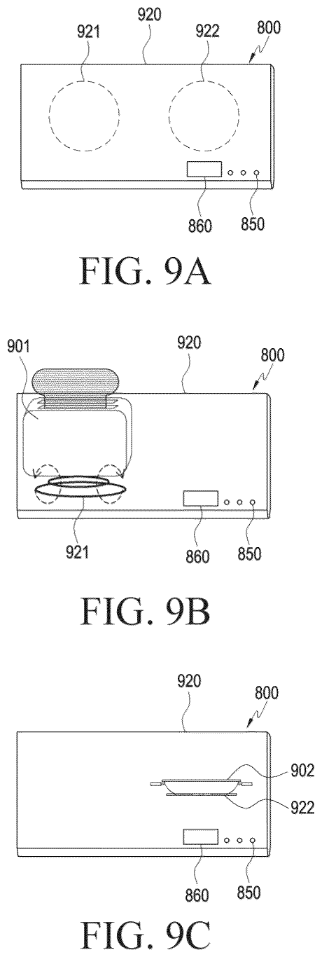

FIG. 9A is a diagram illustrating an example of a hybrid induction device according to an embodiment, FIG. 9B is a diagram illustrating an example in which an external device is placed on the exposed surface of a hybrid induction device according to an embodiment, and FIG. 9C is a diagram illustrating an example in which cooking equipment is placed on the exposed surface of a hybrid induction device according to an embodiment.

Referring to FIG. 9A, the hybrid induction device 800 according to an embodiment may include at least one or more areas 921 and/or 922 on the exposed surface 920, and at least one or more areas 921 and/or 922 may include a cooking-equipment heating area (hereinafter, a description will be made assuming that 922 is a cooking-equipment heating area) and/or a wireless power transmission area (hereinafter, a description will be made assuming that 921 is a wireless power transmission area). The hybrid induction device 800 according to an embodiment may further include a display 860 and/or an input interface 850 in other areas of the exposed surface 920.

Referring to FIG. 9B, the controller 820 of the hybrid induction device 800 according to an embodiment may control first power (e.g., ping power) for sensing an external device (e.g., the wireless power reception device) to be output through the wireless power transmission area 921 using the wireless power transmission circuit 835. According to an embodiment, if an input for transmitting wireless power is received by a user input interface through the input interface 850 or if an external device sensing event is received, the controller 820 may perform control such that the wireless power transmission circuit 835 outputs first power (e.g., ping power) for sensing an external device capable of receiving wireless power through the transmission coil 835-1 before transmitting wireless power. The controller 820 according to an embodiment may identify a first phase of current (e.g., a first current) flowing through the transmission coil 835-1, which is measured using the current sensor 836 while outputting the first power through the wireless power transmission circuit 835. The controller 820 according to an embodiment may compare the first phase of the measured first current with a second phase of a second current in the state where an external device is not in proximity while outputting the first power, thereby identifying a phase delay between the first phase and the second phase. The controller 820 according to an embodiment may identify whether a phase delay value between the first phase of the measured first current and the second phase of the second current in the state where an external device is not in proximity is equal to or greater than (or exceeds) a designated threshold. The controller 820 according to an embodiment, based on the phase delay value between the first phase and the second phase being less than (or equal to or less than) the designated threshold, may identify the state where the external device is not in proximity. The controller 820 according to an embodiment, based on the phase delay between the first phase and the second phase being equal to or greater than the threshold, may identify the state where the external device is in proximity. The controller 820 according to an embodiment may identify the type of external device, based on the phase delay value between the first phase in the state where an external device is in proximity and the second phase. The controller 820 according to an embodiment may store phase delay values corresponding to the respective external devices 110-1 to 110-n and identify (confirm or determine) a phase delay value corresponding to the delay value between the first phase and the second phase, from among the phase delay values of the external devices 110-1 to 110-n. For example, if the delay value between the first phase and the second phase is equal to a first phase delay value among the phase delay values of the external devices 110-1 to 110-n or similar thereto within a designated range, the controller 820 may identify a first external device or a first type of external device corresponding to the first phase delay value. For example, if the delay value between the first phase and the second phase is equal to a second phase delay value among the phase delay values of the external devices 110-1 to 110-n or similar thereto within a designated range, the controller 820 may identify a second external device or a second type of external device corresponding to the second phase delay value. The controller 820 according to an embodiment, based on the identified external device (e.g., the wireless power reception device) 901 (e.g., a toaster) or the type of external device 901, may control the wireless power transmission circuit 835 to transmit wireless power (e.g., second power) to the hybrid induction device 800.

Referring to FIG. 9C, if an input for induction-on (starting heating) is received by a user input interface through the input interface 850, the controller 820 of the hybrid induction device 800 according to an embodiment may supply power to the induction heater 830 to switch to an operation state, and perform an induction heating operation on the cooking-equipment heating area 922 through the induction heater 830, thereby heating the external device (e.g., cooking equipment) 902 by induction.

It should be appreciated that one or more embodiments of the disclosure and the terms used therein are not intended to limit the technological features set forth herein to particular embodiments and include various changes, equivalents, or alternatives for a corresponding embodiment. With regard to the description of the drawings, similar reference numerals may be used to designate similar or relevant elements. It is to be understood that a singular form of a noun corresponding to an item may include one or more of the items, unless the relevant context clearly indicates otherwise. Such terms as “a first,” “a second,” “the first.”

and “the second” may be used to simply distinguish a corresponding element from another, and does not limit the elements in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may be interchangeably used with other terms, for example, “logic,” “logic block,” “component,” or “circuit”. The “module” may be a minimum unit of a single integrated component adapted to perform one or more functions, or a part thereof. For example, according to an embodiment, the “module” may be implemented in the form of an application-specific integrated circuit (ASIC).

One or more embodiments as set forth herein may be implemented as software (e.g., a program) including one or more instructions that are stored in a storage medium (e.g., a memory) that is readable by a machine (e.g., the induction device 100 or 400 or hybrid induction device 800). For example, a processor (e.g., the processor 212 or the controller 820) of the machine (e.g., the induction device 100 or 400 or hybrid induction device 800) may invoke at least one of the one or more instructions stored in the storage medium, and execute it. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to one or more embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., Play Store TM), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to one or more embodiments, each element (e.g., a module or a program) of the above-described elements may include a single entity or multiple entities. According to one or more embodiments, one or more of the above-described elements may be omitted, or one or more other elements may be added. Alternatively or additionally, a plurality of elements (e.g., modules or programs) may be integrated into a single element. In such a case, according to one or more embodiments, the integrated element may still perform one or more functions of each of the plurality of elements in the same or similar manner as they are performed by a corresponding one of the plurality of elements before the integration. According to one or more embodiments, operations performed by the module, the program, or another element may be carried out sequentially, in parallel, repeatedly, or heuristically, or one or more of the operations may be executed in a different order or omitted, or one or more other operations may be added.

According to one or more embodiments, a non-transitory storage medium may store instructions configured to cause, when executed by at least one processor, the at least one processor to perform at least one or more operations, wherein the at least one or more operations may include outputting first power for sensing an external device through wireless power transmission circuit, measuring a first current flowing through a transmission coil of the wireless power transmission circuit by using a current sensor while outputting the first power, identifying a first phase of the measured first current, identifying a phase delay value between the first phase of the first current and a second phase of a second current in the state where an external device is not in proximity, and identifying the state where an external device is in proximity when the identified phase delay value is equal to or greater than a designated threshold.

The embodiments of the disclosure described and shown in the specification and the drawings are merely specific examples that have been presented to easily explain the technical contents of the disclosure and help understanding of the disclosure, and are not intended to limit the scope of the disclosure. Therefore, the scope of the disclosure should be construed to include, in addition to the embodiments disclosed herein, all changes and modifications derived on the basis of the technical idea of the disclosure.

What is claimed is:

1. An induction device comprising:
a wireless power transmission circuit;
a current sensor; and
at least one processor connected to the wireless power transmission circuit and the current sensor,
wherein the at least one processor is configured to:
output first power for detecting an external device through the wireless power transmission circuit,
identify a first phase of a first current by measuring the first current flowing through a transmission coil of the wireless power transmission circuit using the current sensor while outputting the first power,
in a first state where the external device is not in proximity, identify a phase delay value between the first phase of the first current and a second phase of a second current, and
identify a second state where the external device is in proximity when the identified phase delay value is equal to or greater than a designated threshold,
wherein the first state where the external device is in not proximity corresponds to a state where the external device is not on, not vertically above, or not near the induction device, and
wherein the second state where the external device is in proximity corresponds to a state where the external device is on vertically above, or near the induction device.

2. The induction device of claim 1, wherein the at least one processor is further configured to:
identify a first external device corresponding to a first phase delay value when the identified phase delay value is the first phase delay value in the state where the identified phase delay value is equal to or greater than the designated threshold, and
identify a second external device corresponding to a second phase delay value when the identified phase delay value is the second phase delay value.

3. The induction device of claim 1, further comprising memory configured to store a plurality of phase delay values respectively corresponding to a plurality of external devices.

4. The induction device of claim 1, wherein the at least one processor is further configured to identify one external device corresponding to the identified phase delay value from among the plurality of external devices by using the plurality of phase delay values.

5. The induction device of claim 1, wherein the at least one processor is further configured to identify the phase delay, based on a difference between a second crossing point value of the second current in the first state where the external device is not in proximity and a first crossing point value of the measured first current.

6. The induction device of claim 1, wherein the at least one processor is further configured to output the first power for detecting the external device through the wireless power transmission circuit, based on a designated resonance frequency.

7. The induction device of claim 1, further comprising a communication circuit.

8. The induction device of claim 1, wherein the communication circuit is configured to communicate with the external device by an in-band scheme or an out-band scheme.

9. The induction device of claim 1, further comprising an induction heater,
wherein the at least one processor is further configured to control the induction heater and the wireless power transmission circuit, respectively.

10. The induction device of claim 9, further comprising an input interface,
wherein the at least one processor is further configured to perform electromagnetic induction heating through the induction heater when an input for induction heating is received through the input interface.

11. A method of detecting an external device in an induction device, the method comprising:
outputting first power for detecting the external device through wireless power transmission circuit;
measuring a first current flowing through a transmission coil of the wireless power transmission circuit by using a current sensor while outputting the first power;
identifying a first phase of the measured first current;
in a first state where the external device is not in proximity, identifying a phase delay value between the first phase of the first current and a second phase of a second current; and
when the identified phase delay value is equal to or greater than a designated threshold, identifying a second state where the external device is in proximity,
wherein the first state where the external device is in not proximity corresponds to a state where the external device is not on, not vertically above, or not near the induction device, and
wherein the second state where the external device is in proximity corresponds to a state where the external device is on vertically above, or near the induction device.

12. The method of claim 11, further comprising:
identifying a first external device corresponding to a first phase delay value when the identified phase delay value is the first phase delay value in a state where the identified phase delay value is equal to or greater than the designated threshold; and
identifying a second external device corresponding to a second phase delay value when the identified phase delay value is the second phase delay value.

13. The method of claim 11, further comprising obtaining a plurality of phase delay values respectively corresponding to a plurality of external devices.

14. The method of claim 11, further comprising identifying one external device corresponding to the identified phase delay value from among the plurality of external devices by using the plurality of phase delay values.

15. The method of claim 11, further comprising identifying the phase delay, based on a difference between a second crossing point value of the second current in the first state where the external device is not in proximity and a first crossing point value of the measured first current.

16. The method of claim 11, comprising outputting the first power for detecting the external device through the wireless power transmission circuit, based on a designated resonance frequency.

17. The method of claim 11, further comprising communicating with the external device in an in-band scheme or an out-band scheme.

18. The method of claim 11, further comprising controlling an induction heater.

19. The method of claim 18, further comprising when an input for induction heating is received through an input interface, performing electromagnetic induction heating through the induction heater.

20. A non-transitory storage medium storing instructions configured to cause, when executed by at least one processor, the at least one processor to perform at least one or more operations, wherein the at least one or more operations comprise:
outputting first power for detecting an external device through a wireless power transmission circuit;
measuring a first current flowing through a transmission coil of the wireless power transmission circuit by using a current sensor while outputting the first power;
identifying a first phase of the measured first current;
in a first state where the external device is not in proximity, identifying a phase delay value between the first phase of the first current and a second phase of a second current; and
identifying a second state where the external device is in proximity when the identified phase delay value is equal to or greater than a designated threshold.
